(19) United States
(12) Patent Application Publication
(10) Pub. No.: US 2026/0173961 A1
(43) Pub. Date: Jun. 18, 2026

(54) SEMICONDUCTOR PACKAGE INCLUDING A SEMICONDUCTOR CHIP STACK

(71) Applicant: SK hynix Inc., Icheon-si Gyeonggi-do (KR)

(72) Inventor: Ha Gyeong SONG, Icheon-si Gyeonggi-do (KR)

(73) Assignee: SK hynix Inc., Icheon-si Gyeonggi-do (KR)

(21) Appl. No.: 19/190,146

(22) Filed: Apr. 25, 2025

(30) Foreign Application Priority Data
Dec. 12, 2024 (KR) 10-2024-0184299

(51) Int. Cl. H01L 25/065; H01L 23/00; H01L 23/31; H01L 23/538; H10B 80/00

(52) U.S. Cl. CPC H10W 90/00; H10W 70/611; H10W 70/635; H10W 74/117; H10B 80/00; H10W 70/65; H10W 70/652; H10W 72/536; H10W 72/856; H10W 72/859; H10W 72/865; H10W 72/884; H10W 74/00; H10W 90/24; H10W 90/722; H10W 90/732; H10W 90/754

(57) ABSTRACT

A semiconductor package according to embodiments of the present disclosure include a first semiconductor chip including a first bonding pad and a first connection pad connected to the first bonding pad; a second semiconductor chip stacked on the first semiconductor chip, and including a second bonding pad connected to the first connection pad by a first connection bump; a first vertical wire disposed on the first bonding pad; a molding layer sealing the first and second semiconductor chips and the first vertical wire; and a redistribution layer disposed on the molding layer and the first vertical wire.

### CROSS-REFERENCE TO RELATED APPLICATION

The present application claims priority under 35 U.S.C. § 119(a) to Korean Patent Application No. 10-2024-0184299 filed in the Korean Intellectual Property Office on Dec. 12, 2024, which application is incorporated herein by reference in its entirety.

### BACKGROUND

### 1. Technical Field

Embodiments of the present disclosure generally relate to a semiconductor package, and more particularly, to a semiconductor package including a semiconductor chip stack.

### 2. Related Art

Electronic products are required to process high-capacity data while becoming increasingly smaller in volume. Accordingly, there is a growing need to increase the degree of integration of semiconductor devices used in electronic products.

Because it is difficult to satisfy required functions with just a single semiconductor chip due to limitations in integration technology, semiconductor packages are manufactured by stacking a plurality of semiconductor chips.

Even when a semiconductor package includes a plurality of semiconductor chips, the semiconductor package is required to be fabricated to a specified size or smaller depending on the requirements of an application in which the semiconductor package is mounted.

### SUMMARY

In an embodiment, a semiconductor package may include: a first semiconductor chip including a first bonding pad and a first connection pad connected to the first bonding pad; a second semiconductor chip stacked on the first semiconductor chip, and including a second bonding pad connected to the first connection pad by a first connection bump; a first vertical wire disposed on the first bonding pad; a molding layer sealing the first and second semiconductor chips and the first vertical wire; and a redistribution layer disposed on the molding layer and the first vertical wire.

In an embodiment, a semiconductor package may include: a first semiconductor chip including a first bonding pad and a first connection pad connected to the first bonding pad; a second semiconductor chip offset-stacked on the first semiconductor chip to expose the first bonding pad, and including a second bonding pad connected to the first connection pad by a first connection bump; a third semiconductor chip stacked on the second semiconductor chip, and including a third bonding pad and a second connection pad connected to the third bonding pad; a fourth semiconductor chip offset-stacked on the third semiconductor chip to expose the third bonding pad, and including a fourth bonding pad connected to the second connection pad by a second connection bump; a first vertical wire disposed on the first bonding pad; a second vertical wire disposed on the third bonding pad; a molding layer sealing the first, second, third and fourth semiconductor chips and the first and second vertical wires; and a redistribution layer disposed on the molding layer and the first and second vertical wires.

### BRIEF DESCRIPTION OF THE DRAWINGS

FIG. 1 and FIG. 2 are cross-sectional views of a semiconductor package according to an embodiment of the present disclosure.

FIG. 3 is a perspective view illustrating a chip stack included in a semiconductor package according to an embodiment of the present disclosure.

FIG. 4 is a plan view illustrating the disposition of pads of a first semiconductor chip according to an embodiment of the present disclosure.

FIG. 5 is a cross-sectional view taken along a line C-C′ of FIG. 4.

FIG. 6 is a cross-sectional view taken along a line D-D′ of FIG. 4.

FIG. 7 and FIG. 8 are cross-sectional views of a semiconductor package according to an embodiment of the present disclosure.

FIG. 9 is a cross-sectional view of a semiconductor package including a comparative example of a semiconductor chip stack.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “under,” or “beneath” another element, the elements may directly contact each other or an intervening element may be disposed between the elements.

Terms such as “vertical,” “top,” “bottom,” “under,” “on,” “side,” “upper,” “lower,” “column,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure. In an embodiment, ‘VD’ may indicate the vertical direction, HD1 may indicate a first horizontal direction and HD2 may indicate a second horizontal direction. In an embodiment, the first and second horizontal directions HD1 and HD2 may form a plane and the vertical direction VD may intersect the plane.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

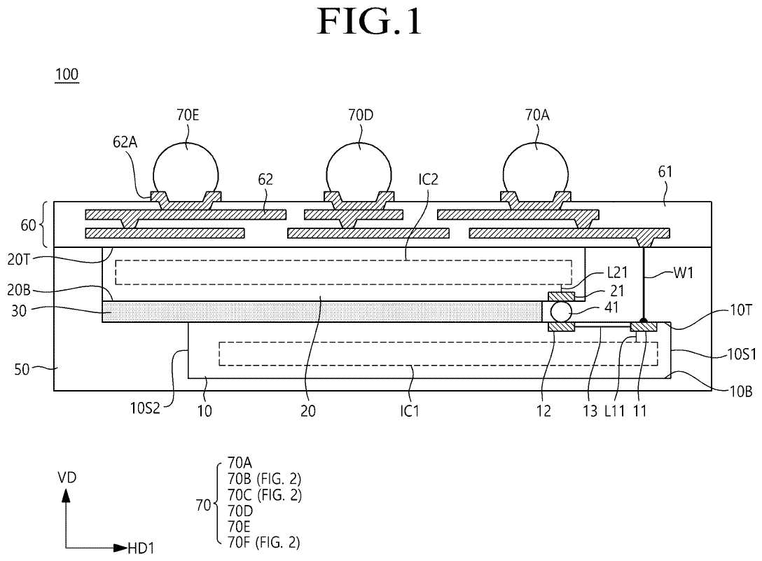

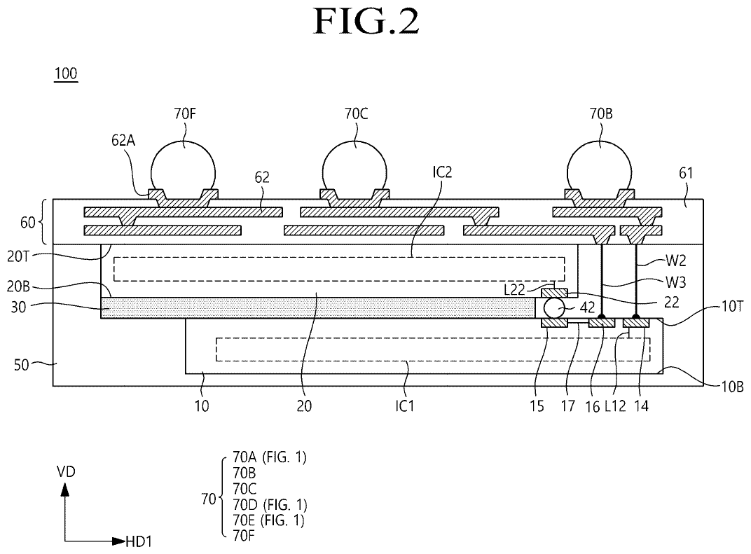

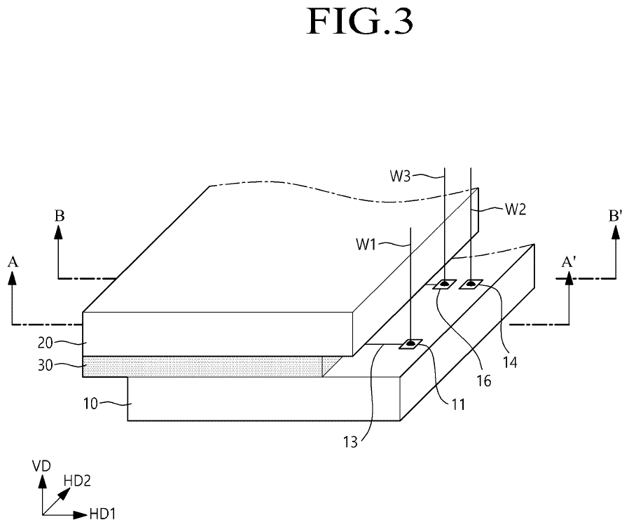

FIG. 1 and FIG. 2 are cross-sectional views of a semiconductor package according to an embodiment of the present disclosure, and FIG. 3 is a perspective view illustrating a chip stack included in a semiconductor package according to an embodiment of the present disclosure. FIG. 1 illustrates a cross-section of a semiconductor package corresponding to a line A-A′ of FIG. 3, and FIG. 2 illustrates a cross-section of the semiconductor package corresponding to a line B-B′ of FIG. 3.

Referring to FIG. 1 to FIG. 3, a semiconductor package 100 according to an embodiment of the present disclosure includes a first semiconductor chip 10, a second semiconductor chip 20, first, second and third vertical wires W1, W2 and W3, first and second connection bumps 41 and 42, a molding layer 50, and a redistribution layer 60. Besides, the semiconductor package 100 further includes external connection terminals 70.

The first semiconductor chip 10 includes a first integrated circuit IC1, and has a top surface 10T on which bonding pads 11, 14 and 16 and connection pads 12 and 15 are located and a bottom surface 10B opposite to the top surface 10T.

The first integrated circuit IC1 may be implemented in various ways depending on the type of the first semiconductor chip 10. In an embodiment, the first semiconductor chip 10 may be a memory chip, and the first integrated circuit IC1 may include memory cells. Memory may include volatile memory or nonvolatile memory. Volatile memory may include dynamic random access memory (DRAM) and static random access memory (SRAM). Nonvolatile memory may include NAND, NOR, phase change random access memory (PRAM) and magneto-resistive random access memory (MRAM).

The bonding pads 11, 14 and 16 and the connection pads 12 and 15 are disposed at an edge section of the top surface 10T of the first semiconductor chip 10. The bonding pads 11, 14 and 16 include a first bonding pad 11, a second bonding pad 14 and a third bonding pad 16. The first bonding pad 11 is connected to the first integrated circuit IC1 through a first internal wiring L11 of the first semiconductor chip 10. The second bonding pad 14 is connected to the first integrated circuit IC1 through a second internal wiring L12 of the first semiconductor chip 10. The first bonding pad 11 may include a data pad. The second bonding pad 14 may include a command/address pad or a chip select pad. The data pad is an external contact of the first semiconductor chip 10 for the input and the output of data signal to and from external devices (not shown). The command/address pad is an external contact of the first semiconductor chip 10 for the input of command/address signals from the external devices. The chip select pad is an external contact of the first semiconductor chip 10 for the input of the chip select signals from the external devices.

The connection pads 12 and 15 include a first connection pad 12 and a second connection pad 15.

The first connection pad 12 is connected to the first bonding pad 11 through a first trace 13. The first connection pad 12 is connected to the first integrated circuit IC1 through the first trace 13, the first bonding pad 11 and the first internal wiring L11.

The second connection pad 15 is connected to the third bonding pad 16 through a second trace 17. The second connection pad 15 and the third bonding pad 16 are not connected to the first integrated circuit IC1. In other words, the second connection pad 15 and the third bonding pad 16 are electrically isolated from the first integrated circuit IC1.

The second semiconductor chip 20 is stacked on the first semiconductor chip 10. The second semiconductor chip 20 is offset-stacked on the first semiconductor chip 10 to expose the first, second and third bonding pads 11, 14 and 16.

The second semiconductor chip 20 includes a second integrated circuit IC2, and has a bottom surface 20B on which bonding pads 21 and 22 are disposed and a top surface 20T opposite to the bottom surface 20B. The second semiconductor chip 20 may be a chip of the same type as the first semiconductor chip 10. In an embodiment, the first and second semiconductor chips 10 and 20 may be memory chips, and the first and second integrated circuits IC1 and IC2 may include memory cells.

The bonding pads 21 and 22 are disposed at an edge section of the bottom surface 20B of the second semiconductor chip 20. The bonding pads 21 and 22 include a fourth bonding pad 21 and a fifth bonding pad 22. The fourth bonding pad 21 is connected to the second integrated circuit IC2 through a third internal wiring L21 of the second semiconductor chip 20. The fifth bonding pad 22 is connected to the second integrated circuit IC2 through a fourth internal wiring L22 of the second semiconductor chip 20. The fourth bonding pad 21 may include a data pad. The fifth bonding pad 22 may include a command/address pad or a chip select pad. The data pad is an external contact of the second semiconductor chip 20 for the input and the output of data signal to and from external devices (not shown). The command/address pad is an external contact of the second semiconductor chip 20 for the input of command/address signals from the external devices. The chip select pad is an external contact of the second semiconductor chip 20 for the input of the chip select signals from the external devices.

The fourth bonding pad 21 of the second semiconductor chip 20 vertically overlaps the first connection pad 12 of the first semiconductor chip 10, and the first connection bump 41 is disposed between the fourth bonding pad 21 and the first connection pad 12. The fourth bonding pad 21 is connected to the first connection pad 12 by the medium of the first connection bump 41. The fourth bonding pad 21 is connected to the first bonding pad 11 through the first connection bump 41, the first connection pad 12 and the first trace 13.

The fifth bonding pad 22 of the second semiconductor chip 20 vertically overlaps the second connection pad 15 of the first semiconductor chip 10, and the second connection bump 42 is disposed between the fifth bonding pad 22 and the second connection pad 15. The fifth bonding pad 22 is connected to the second connection pad 15 by the medium of the second connection bump 42. The fifth bonding pad 22 is connected to the third bonding pad 16 through the second connection bump 42, the second connection pad 15 and the second trace 17.

A first adhesive layer 30 is disposed on the bottom surface 20B of the second semiconductor chip 20. The first adhesive layer 30 attaches the bottom surface 20B of the second semiconductor chip 20 to the top surface 10T of the first semiconductor chip 10.

The first, second and third vertical wires W1, W2 and W3 are connected to the first, second and third bonding pads 11, 14 and 16, respectively. The first vertical wire W1 extends substantially vertically with its lower end connected to the first bonding pad 11. The second vertical wire W2 extends substantially vertically with its lower end connected to the second bonding pad 14. The third vertical wire W3 extends substantially vertically with its lower end connected to the third bonding pad 16. The first, second and third vertical wires W1, W2 and W3 may be formed of a conductive material. The conductive material may include gold (Au).

The molding layer 50 is formed to cover the first and second semiconductor chips 10 and 20, the first and second connection bumps 41 and 42 and the first, second and third vertical wires W1, W2 and W3. The molding layer 50 may seal the first and second semiconductor chips 10 and 20, the first and second connection bumps 41 and 42 and the first, second and third vertical wires W1, W2 and W3 to protect the first and second semiconductor chips 10 and 20, the first and second connection bumps 41 and 42 and the first, second and third vertical wires W1, W2 and W3 from an external environment.

The molding layer 50 includes an insulating layer. The insulating layer may include an epoxy molding compound (EMC). The epoxy molding compound may include resin and filler.

The upper ends of the first, second and third vertical wires W1, W2 and W3 are exposed on the top surface of the molding layer 50. The redistribution layer 60 is disposed on the molding layer 50 and the first, second and third vertical wires W1, W2 and W3.

The redistribution layer 60 includes a dielectric layer 61 and redistribution patterns 62. Each of the redistribution patterns 62 is connected to one of the first, second and third vertical wires W1, W2 and W3 and is connected to the first second semiconductor chip 10 or the second semiconductor chip 20 through the one of the first, second and third vertical wires W1, W2 and W3. The redistribution patterns 62 are insulated from each other by the dielectric layer 61.

Some of the redistribution patterns 62 include under bump metallurgies (UBMs) 62A. The external connection terminals 70 are connected to the UBMs 62A, respectively. The UBMs 62A serve as a wetting layer so that the external connection terminals 70 may be well adhered. The external connection terminals 70 include solder balls. Each of the external connection terminals 70 may be connected to one of the first, second and third vertical wires W1, W2 and W3 through a corresponding redistribution pattern 62. The external connection terminals 70 include first to sixth external connection terminals 70A to 70F.

The first, second and third vertical wires W1, W2 and W3 are connected to different external connection terminals 70. The first external connection terminal 70A is connected to the first vertical wire W1, the second external connection terminal 70B is connected to the second vertical wire W2, and the third external connection terminal 70C is connected to the third vertical wire W3. The first external connection terminal 70A is connected to an external device, for example, a memory controller, through a first channel (not illustrated). The second external connection terminal 70B is connected to the external device through a second channel (not illustrated). The third external connection terminal 70C is connected to the external device through a third channel (not illustrated).

The first bonding pad 11 of the first semiconductor chip 10 and the fourth bonding pad 21 of the second semiconductor chip 20 are connected in common to the first external connection terminal 70A, and are connected to the external device through the first channel connected to the first external connection terminal 70A. The first semiconductor chip 10 and the second semiconductor chip 20 share the first channel. A signal input to the first external connection terminal 70A through the first channel from the external device may be transmitted to the first bonding pad 11 of the first semiconductor chip 10 through the redistribution pattern 62 and the first vertical wire W1, or may be transmitted to the fourth bonding pad 21 of the second semiconductor chip 20 through the redistribution pattern 62, the first vertical wire W1, the first bonding pad 11, the first trace 13, the first connection pad 12 and the first connection bump 41.

The second bonding pad 14 of the first semiconductor chip 10 is connected to the second external connection terminal 70B, and is connected to the external device through the second channel connected to the second external connection terminal 70B. The fifth bonding pad 22 of the second semiconductor chip 20 is connected to the third external connection terminal 70C, and is connected to the external device through the third channel connected to the third external connection terminal 70C. The second bonding pad 14 of the first semiconductor chip 10 and the fifth bonding pad 22 of the second semiconductor chip 20 may be the same type of pads, and may be connected to the external device through different channels. A signal input to the second external connection terminal 70B from the external device is transmitted to the second bonding pad 14 of the first semiconductor chip 10 through the redistribution pattern 62 and the second vertical wire W2. A signal input to the third external connection terminal 70C from the external device is transmitted to the fifth bonding pad 22 of the second semiconductor chip 20 through the redistribution pattern 62, the third vertical wire W3, the third bonding pad 16, the second trace 17, the second connection pad 15 and the second connection bump 42. While one of the first and second semiconductor chips 10 and 20 that share the first channel operates, the other is in a standby state.

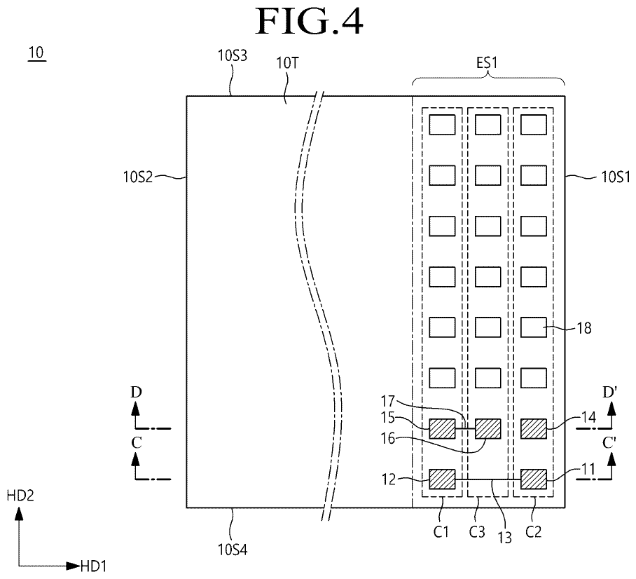

FIG. 4 is a plan view illustrating the disposition of pads of a first semiconductor chip according to an embodiment of the present disclosure.

Referring to FIG. 1 and FIG. 4, the first semiconductor chip 10 has the top surface 10T on which pads 11, 12, 14, 15, 16 and 18 are disposed, the bottom surface 10B (see FIG. 1) opposite to the top surface 10T, and side surfaces 10S1, 10S2, 10S3 and 10S4 that connect the top surface 10T and the bottom surface 10B. The side surfaces 10S1, 10S2, 10S3 and 10S4 of the first semiconductor chip 10 include two side surfaces 10S1 and 10S2 that face each other in a first direction HD1 parallel to the top surface 10T, and two side surfaces 10S3 and 10S4 that face each other in a second direction HD2 parallel to the top surface 10T and perpendicular to the first direction HD1. Hereinafter, two side surfaces facing each other in the first direction HD1 will be referred to as a first side surface 10S1 and a second side surface 10S2, and two side surfaces facing each other in the second direction HD2 will be referred to as a third side surface 10S3 and a fourth side surface 10S4.

The first semiconductor chip 10 includes first, second and third pad columns C1, C2 and C3 located at an edge section ES1 including the first side surface 10S1. In each of the first, second and third pad columns C1, C2 and C3, a plurality of pads may be disposed in a line in the second direction HD2. The second pad column C2 is located between the first side surface 10S1 and the first pad column C1, and the third pad column C3 is located between the first pad column C1 and the second pad column C2.

The first and second bonding pads 11 and 14 are included in the second pad column C2, the first and second connection pads 12 and 15 are included in the first pad column C1, and the third bonding pad 16 is included in the third pad column C3.

The second semiconductor chip 20 is offset-stacked on the first semiconductor chip 10 to expose the second and third pad columns C2 and C3.

For the sake of simplicity in explanation, FIG. 4 illustrates only one first bonding pad 11 and only one second bonding pad 14, but it is to be noted that the first semiconductor chip 10 may include a plurality of first bonding pads and a plurality of second bonding pads. First connection pads are provided in the same number as first bonding pads, and second connection pads and third bonding pads are each provided in the same number as second bonding pads.

A pad denoted by the reference numeral 18 in FIG. 4 is to explain a pad column, and the pad 18 may take charge of inputting or/and outputting a preset signal. For the sake of simplicity in explanation, the role or function of the pad 18 will not be specified in the present specification.

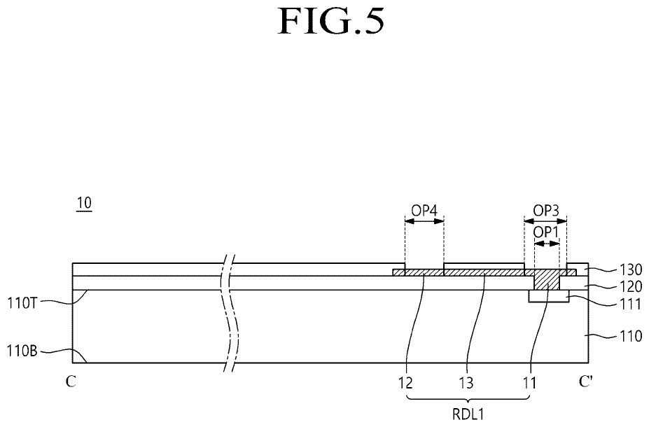

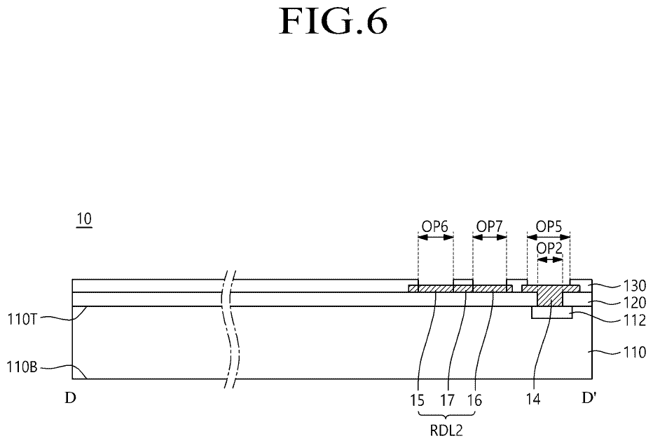

FIG. 5 is a cross-sectional view taken along a line C-C′ of FIG. 4, and FIG. 6 is a cross-sectional view taken along a line D-D′ of FIG. 4.

Referring to FIG. 5 and FIG. 6, the first semiconductor chip 10 includes a chip body 110, first and second insulating layers 120 and 130, first and second redistribution patterns RDL1 and RDL2, and the second bonding pad 14.

The chip body 110 includes the first integrated circuit IC1 (see FIG. 1), and has a first surface 110T on which chip pads 111 and 112 are located and a second surface 110B opposite to the first surface 110T. The second surface 110B of the chip body 110 constitutes the bottom surface 10B (see FIG. 1) of the first semiconductor chip 10. The chip pads 111 and 112 include a first chip pad 111 and a second chip pad 112. The first and second chip pads 111 and 112 are connected to the first integrated circuit IC1. The first chip pad 111 may be an external contact point of the chip body 110 for input/output of a data signal. The second chip pad 112 may be an external contact point of the chip body 110 for input of a command/address signal or a chip select signal.

The first insulating layer 120 is disposed on the first surface 110T of the chip body 110. The first insulating layer 120 may cover the first surface 110T of the chip body 110, and may expose the first and second chip pads 111 and 112. The first insulating layer 120 has a first opening OP1 through which the first chip pad 111 is exposed and a second opening OP2 through which the second chip pad 112 is exposed.

The first insulating layer 120 may isolate the first and second redistribution patterns RDL1 and RDL2 from the chip body 110. The first insulating layer 120 may include a photosensitive polymer material such as polyimide.

The first redistribution pattern RDL1 is disposed on the first insulating layer 120 and the first chip pad 111 exposed through the first opening OP1. The first redistribution pattern RDL1 includes the first bonding pad 11, the first connection pad 12 and the first trace 13. The first bonding pad 11 is disposed on the first chip pad 111 and is connected to the first chip pad 111. The first connection pad 12 and the first trace 13 are disposed on the first insulating layer 120. The first connection pad 12 is spaced apart from the first bonding pad 11, and the first trace 13 connects the first connection pad 12 and the first bonding pad 11.

The second bonding pad 14 is disposed on the second chip pad 112 and is connected to the second chip pad 112. The second redistribution pattern RDL2 is disposed on the first insulating layer 120. The second redistribution pattern RDL2 is spaced apart from the second bonding pad 14. The second redistribution pattern RDL2 includes the second connection pad 15, the third bonding pad 16 and the second trace 17.

The second insulating layer 130 is disposed on the first insulating layer 120 and the first and second redistribution patterns RDL1 and RDL2. In an embodiment, the second insulating layer 130 may protect the first and second redistribution patterns RDL1 and RDL2. The second insulating layer 130 may include a photosensitive polymer material such as polyimide. The top surface of the second insulating layer 130 may constitute the top surface 10T (see FIG. 1) of the first semiconductor chip 10.

The second insulating layer 130 may cover the first and second traces 13 and 17 and may expose the first, second and third bonding pads 11, 14 and 16 and the first and second connection pads 12 and 15. The second insulating layer 130 includes a third opening OP3 through which the first bonding pad 11 is exposed, a fourth opening OP4 through which the first connection pad 12 is exposed, a fifth opening OP5 through which the second bonding pad 14 is exposed, a sixth opening OP6 through which the second connection pad 15 is exposed, and a seventh opening OP7 through which the third bonding pad 16 is exposed.

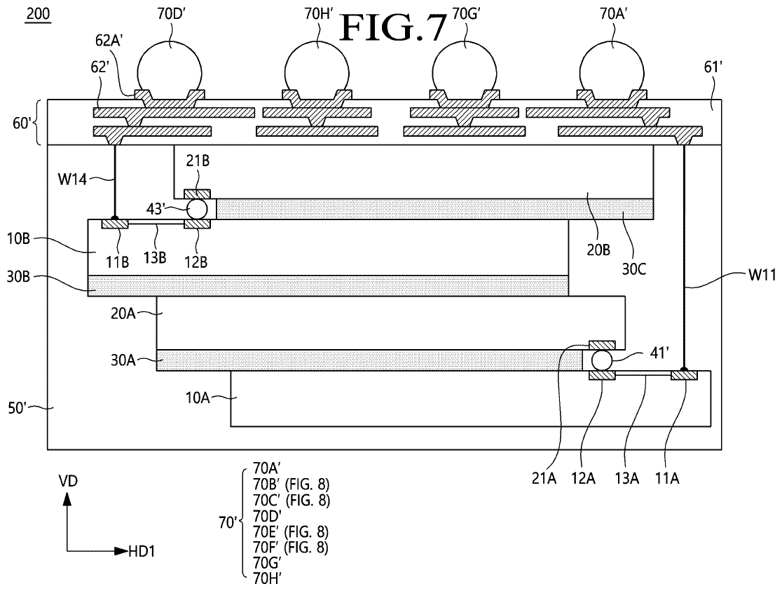

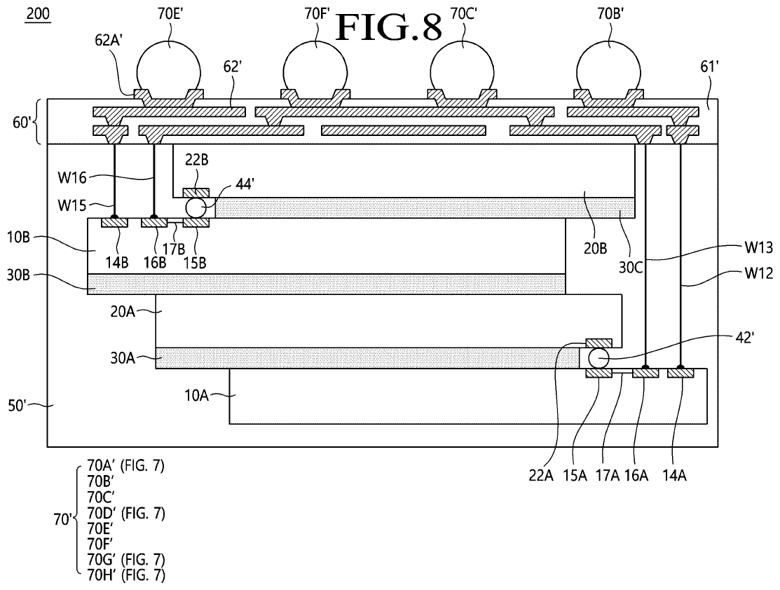

FIG. 7 and FIG. 8 are cross-sectional views of a semiconductor package according to an embodiment of the present disclosure.

Referring to FIG. 7 and FIG. 8, a semiconductor package 200 according to an embodiment of the present disclosure includes first, second, third and fourth semiconductor chips 10A, 20A, 10B and 20B, first, second, third, fourth, fifth and sixth vertical wires W11, W12, W13, W14, W15 and W16, first, second, third and fourth connection bumps 41′, 42′, 43′and 44′, a molding layer 50′, and a redistribution layer 60′.

The first semiconductor chip 10A has bonding pads 11A, 14A and 16A and connection pads 12A and 15A that are disposed at an edge section of a top surface. The bonding pads 11A, 14A and 16A of the first semiconductor chip 10 include a first bonding pad 11A, a second bonding pad 14A and a third bonding pad 16A. The first semiconductor chip 10A includes a first integrated circuit (not illustrated), and the first and second bonding pads 11A and 14A are connected to the first integrated circuit. The first bonding pad 11A may include a data pad. The second bonding pad 14A may include a command/address pad or a chip select pad.

The connection pads 12A and 15A of the first semiconductor chip 10A include a first connection pad 12A and a second connection pad 15A.

The first connection pad 12A is connected to the first bonding pad 11A through a first trace 13A. The first connection pad 12A is connected to the first integrated circuit through the first trace 13A and the first bonding pad 11A.

The second connection pad 15A is connected to the third bonding pad 16A through a second trace 17A. The second connection pad 15A and the third bonding pad 16A are not connected to the first integrated circuit.

The second semiconductor chip 20A is first offset-stacked on the first semiconductor chip 10A. The second semiconductor chip 20A is offset with respect to the first semiconductor chip 10A to expose the first, second and third bonding pads 11A, 14A and 16A.

The second semiconductor chip 20A includes a second integrated circuit (not illustrated) and bonding pads 21A and 22A that are disposed at an edge section of a bottom surface. The second semiconductor chip 20A may be a chip of the same type as the first semiconductor chip 10A. In an embodiment, the first and second semiconductor chips 10A and 20A may be memory chips, and the first and second integrated circuits may include memory cells.

The bonding pads 21A and 22A of the second semiconductor chip 20A include a fourth bonding pad 21A and a fifth bonding pad 22A. The fourth and fifth bonding pads 21A and 22A are connected to the second integrated circuit. The fourth bonding pad 21A may include a data pad. The fifth bonding pad 22A may include a command/address pad or a chip select pad.

The fourth bonding pad 21A of the second semiconductor chip 20A vertically overlaps the first connection pad 12A of the first semiconductor chip 10A, and the first connection bump 41′ is disposed between the fourth bonding pad 21A and the first connection pad 12A. The fourth bonding pad 21A is connected to the first connection pad 12A by the medium of the first connection bump 41′. The fourth bonding pad 21A is connected to the first bonding pad 11A through the first connection bump 41′, the first connection pad 12A and the first trace 13A.

The fifth bonding pad 22A of the second semiconductor chip 20A vertically overlaps the second connection pad 15A of the first semiconductor chip 10A, and the second connection bump 42′ is disposed between the fifth bonding pad 22A and the second connection pad 15A. The fifth bonding pad 22A is connected to the second connection pad 15A by the medium of the second connection bump 42′. The fifth bonding pad 22A is connected to the third bonding pad 16A through the second connection bump 42′, the second connection pad 15A and the second trace 17A.

A first adhesive layer 30A is disposed on the bottom surface of the second semiconductor chip 20A, and the second semiconductor chip 20A is attached to the top surface of the first semiconductor chip 10A by the medium of the first adhesive layer 30A.

The third semiconductor chip 10B is second offset-stacked on the second semiconductor chip 20A. A direction in which the third semiconductor chip 10B is offset with respect to the second semiconductor chip 20A may be the same as a direction in which the second semiconductor chip 20A is offset with respect to the first semiconductor chip 10a.

The third semiconductor chip 10B has bonding pads 11B, 14B and 16B and connection pads 12B and 15B on the top surface thereof. The bonding pads 11B, 14B and 16B of the third semiconductor chip 10B include a sixth bonding pad 11B, a seventh bonding pad 14B and an eighth bonding pad 16B. The third semiconductor chip 10B includes a third integrated circuit (not illustrated), and the sixth and seventh bonding pads 11B and 14B are connected to the third integrated circuit. The sixth bonding pad 11B may include a data pad. The seventh bonding pad 14B may include a command/address pad or a chip select pad.

The connection pads 12B and 15B of the third semiconductor chip 10B include a third connection pad 12B and a fourth connection pad 15B.

The third connection pad 12B is connected to the sixth bonding pad 11B through a third trace 13B. The third connection pad 12B is connected to the third integrated circuit through the third trace 13B and the sixth bonding pad 11B. The fourth connection pad 15B is connected to the eighth bonding pad 16B through a fourth trace 17B. The fourth connection pad 15B and the eighth bonding pad 16B are not connected to the third integrated circuit.

A second adhesive layer 30B is disposed on the bottom surface of the third semiconductor chip 10B, and the third semiconductor chip 10B is attached to the top surface of the second semiconductor chip 20A by the medium of the second adhesive layer 30B.

The fourth semiconductor chip 20B is third offset-stacked on the third semiconductor chip 10B.

The fourth semiconductor chip 20B may be offset with respect to the third semiconductor chip 10B to expose the sixth, seventh and eighth bonding pads 11B, 14B and 16B of the third semiconductor chip 10B. A direction in which the fourth semiconductor chip 20B is offset with respect to the third semiconductor chip 10B may be opposite to the direction in which the third semiconductor chip 10B is offset with respect to the second semiconductor chip 20A.

The fourth semiconductor chip 20B includes a fourth integrated circuit (not illustrated) and bonding pads 21B and 22B that are disposed at an edge section of a bottom surface. The fourth semiconductor chip 20B may be a chip of the same type as the third semiconductor chip 10B. In an embodiment, the third and fourth semiconductor chips 10B and 20B may be memory chips, and the third and fourth integrated circuits may include memory cells.

The bonding pads 21B and 22B of the fourth semiconductor chip 20B include a ninth bonding pad 21B and a tenth bonding pad 22B. The ninth and tenth bonding pads 21B and 22B are connected to the fourth integrated circuit. The ninth bonding pad 21B may include a data pad. The tenth bonding pad 22B may include a command/address pad or a chip select pad.

The ninth bonding pad 21B of the fourth semiconductor chip 20B overlaps the third connection pad 12B of the third semiconductor chip 10B, and the third connection bump 43′ is disposed between the ninth bonding pad 21B and the third connection pad 12B. The ninth bonding pad 21B is connected to the third connection pad 12B by the medium of the third connection bump 43′. The ninth bonding pad 21B is connected to the sixth bonding pad 11B through the third connection bump 43′, the third connection pad 12B and the third trace 13B.

The tenth bonding pad 22B of the fourth semiconductor chip 20B vertically overlaps the fourth connection pad 15B of the third semiconductor chip 10B, and the fourth connection bump 44′ is disposed between the tenth bonding pad 22B and the fourth connection pad 15B. The tenth bonding pad 22B is connected to the fourth connection pad 15B by the medium of the fourth connection bump 44′. The tenth bonding pad 22B is connected to the eighth bonding pad 16B through the fourth connection bump 44′, the fourth connection pad 15B and the fourth trace 17B.

A third adhesive layer 30C is disposed on the bottom surface of the fourth semiconductor chip 20B, and the fourth semiconductor chip 20B is attached to the top surface of the third semiconductor chip 10B by the medium of the third adhesive layer 30C.

The first, second, third, fourth, fifth and sixth vertical wires W11, W12, W13, W14, W15 and W16 are connected to the first, second, third, sixth, seventh and eighth bonding pads 11A, 14A, 16A, 11B, 14B and 16B, respectively.

The first vertical wire W11 extends substantially vertically with its lower end connected to the first bonding pad 11A. The second vertical wire W12 extends substantially vertically with its lower end connected to the second bonding pad 14A. The third vertical wire W13 extends substantially vertically with its lower end connected to the third bonding pad 16A. The fourth vertical wire W14 extends substantially vertically with its lower end connected to the sixth bonding pad 11B. The fifth vertical wire W15 extends substantially vertically with its lower end connected to the seventh bonding pad 14B. The sixth vertical wire W16 extends substantially vertically with its lower end connected to the eighth bonding pad 16B. The first, second, third, fourth, fifth and sixth vertical wires W11, W12, W13, W14, W15 and W16 may be formed of a conductive material. The conductive material may include gold.

The molding layer 50′is formed to cover the first, second, third and fourth semiconductor chips 10A, 20A, 10B and 20B, the first, second, third and fourth connection bumps 41′, 42′, 43′ and 44′ and the first, second, third, fourth, fifth and sixth vertical wires W11, W12, W13, W14, W15 and W16. The molding layer 50′seals the first, second, third and fourth semiconductor chips 10A, 20A, 10B and 20B, the first, second, third and fourth connection bumps 41′, 42′, 43′ and 44′ and the first, second, third, fourth, fifth and sixth vertical wires W11, W12, W13, W14, W15 and W16.

The upper ends of the first, second, third, fourth, fifth and sixth vertical wires W11, W12, W13, W14, W15 and W16 are exposed on the top surface of the molding layer 50′. The redistribution layer 60′ is disposed on the molding layer 50′ and the first, second, third, fourth, fifth and sixth vertical wires W11, W12, W13, W14, W15 and W16.

The redistribution layer 60′ includes a dielectric layer 61′ and redistribution patterns 62′. Some of the redistribution patterns 62′ include UBMs 62A′. External connection terminals 70′ are connected to the UBMs 62A′, respectively. The external connection terminals 70′ include solder balls. Each of the external connection terminals 70′ may be connected to one of the first, second, third, fourth, fifth and sixth vertical wires W11, W12, W13, W14, W15 and W16 through a corresponding redistribution pattern 62′.

The external connection terminals 70′ include first, second, third, fourth, fifth, sixth, seventh and eighth external connection terminals 70A′, 70B′, 70C′, 70D′, 70E′, 70F′, 70G′ and 70H′. The first, second, third, fourth, fifth and sixth vertical wires W11, W12, W13, W14, W15 and W16 are connected to different external connection terminals 70′. The first, second, third, fourth, fifth and sixth external connection terminals 70A′, 70B′, 70C′, 70D′, 70E′ and 70F′ are connected to the first, second, third, fourth, fifth and sixth vertical wires W11, W12, W13, W14, W15 and W16, respectively. The first external connection terminal 70A′ is connected to an external device, for example, a memory controller, through a first channel (not illustrated), the second external connection terminal 70B′ is connected to the external device through a second channel (not illustrated), the third external connection terminal 70C′ is connected to the external device through a third channel (not illustrated), the fourth external connection terminal 70D′ is connected to the external device through a fourth channel (not illustrated), the fifth external connection terminal 70E′ is connected to the external device through a fifth channel (not illustrated), and the sixth external connection terminal 70F′ is connected to the external device through a sixth channel (not illustrated).

The first bonding pad 11A of the first semiconductor chip 10A and the fourth bonding pad 21A of the second semiconductor chip 20A are connected in common to the first external connection terminal 70A′, and are connected to the external device through the first channel connected to the first external connection terminal 70A′. The first semiconductor chip 10A and the second semiconductor chip 20A share the first channel. A signal input to the first external connection terminal 70A′ through the first channel from the external device is transmitted to the first bonding pad 11A of the first semiconductor chip 10A through the redistribution pattern 62′ and the first vertical wire W11, or is transmitted to the fourth bonding pad 21A of the second semiconductor chip 20A through the redistribution pattern 62′, the first vertical wire W11, the first bonding pad 11A, the first trace 13A, the first connection pad 12A and the first connection bump 41′.

The second bonding pad 14A of the first semiconductor chip 10A is connected to the second external connection terminal 70B′, and is connected to the external device through the second channel connected to the second external connection terminal 70B′. The fifth bonding pad 22A of the second semiconductor chip 20A is connected to the third external connection terminal 70C′, and is connected to the external device through the third channel connected to the third external connection terminal 70C′. The second bonding pad 14A of the first semiconductor chip 10A and the fifth bonding pad 22A of the second semiconductor chip 20A are the same type of pads, and are connected to the external device through different channels. A signal input to the second external connection terminal 70B′ through the second channel from the external device is transmitted to the second bonding pad 14A of the first semiconductor chip 10A through the redistribution pattern 62′ and the second vertical wire W12. A signal input to the third external connection terminal 70C′ through the third channel from the external device is transmitted to the fifth bonding pad 22A of the second semiconductor chip 20A through the redistribution pattern 62′, the third vertical wire W13, the third bonding pad 16A, the second trace 17A, the second connection pad 15A and the second connection bump 42′.

The sixth bonding pad 11B of the third semiconductor chip 10B and the ninth bonding pad 21B of the fourth semiconductor chip 20B are connected in common to the fourth external connection terminal 70D′, and are connected to the external device through the fourth channel connected to the fourth external connection terminal 70D′. The third semiconductor chip 10B and the fourth semiconductor chip 20B share the fourth channel. A signal input to the fourth external connection terminal 70D′ through the fourth channel from the external device is transmitted to the sixth bonding pad 11B of the third semiconductor chip 10B through the redistribution pattern 62′ and the fourth vertical wire W14, or is transmitted to the ninth bonding pad 21B of the fourth semiconductor chip 20B through the redistribution pattern 62′, the fourth vertical wire W14, the sixth bonding pad 11B, the third trace 13B, the third connection pad 12B and the third connection bump 43′.

The seventh bonding pad 14B of the third semiconductor chip 10B is connected to the fifth external connection terminal 70E′, and is connected to the external device through the fifth channel connected to the fifth external connection terminal 70E′. The tenth bonding pad 22B of the fourth semiconductor chip 20B is connected to the sixth external connection terminal 70F′, and is connected to the external device through the sixth channel connected to the sixth external connection terminal 70F′. The seventh bonding pad 14B of the third semiconductor chip 10B and the tenth bonding pad 22B of the fourth semiconductor chip 20B are the same type of pads, and are connected to the external device through different channels.

A signal input to the fifth external connection terminal 70E′ through the fifth channel from the external device is transmitted to the seventh bonding pad 14B of the third semiconductor chip 10B through the redistribution pattern 62′ and the fifth vertical wire W15. A signal input to the sixth external connection terminal 70F′ through the sixth channel from the external device is transmitted to the tenth bonding pad 22B of the fourth semiconductor chip 20B through the redistribution pattern 62′, the sixth vertical wire W16, the eighth bonding pad 16B, the fourth trace 17B, the fourth connection pad 15B and the fourth connection bump 44′.

While one of the first and second semiconductor chips 10A and 20A that share the first channel operates, the other is in a standby state, and while one of the third and fourth semiconductor chips 10B and 20B that share the fourth channel operates, the other is in a standby state.

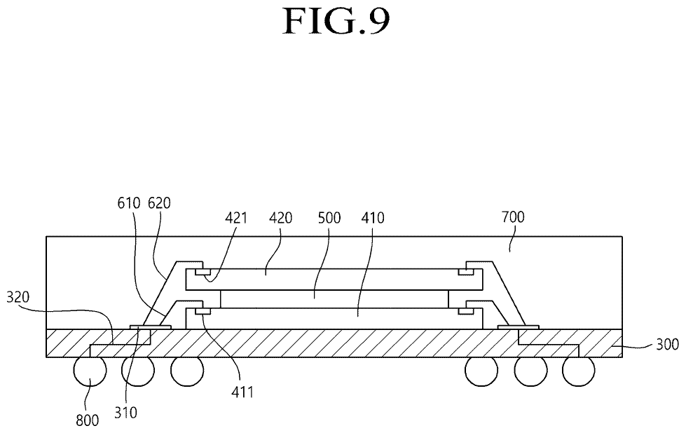

FIG. 9 is a cross-sectional view of a semiconductor package including a comparative example of a semiconductor chip stack.

Referring to FIG. 9, a lower semiconductor chip 410 is stacked on a package substrate 300, and an upper semiconductor chip 420 is stacked on the lower semiconductor chip 410. An adhesive member 500 is disposed between the upper semiconductor chip 420 and the lower chip 410. The upper semiconductor chip 420 is attached to the lower chip 410 via the adhesive member 500.

A first wire 610 is connected between a bonding pad 411 of the lower semiconductor chip 410 and a first bond finger 310 of the package substrate 300, and a second wire 620 is connected between a bonding pad 421 of the upper semiconductor chip 420 and the first bond finger 310 of the package substrate 300. The first bond finger 310 is connected to an external connection terminal 800 that is disposed on the bottom surface of the package substrate 300, through an internal wiring 320 of the package substrate 300. A signal input to the external connection terminal 800 through a channel (not illustrated) from an external device (not illustrated) is transmitted to the lower semiconductor chip 410 through the internal wiring 320 and the first bond finger 310 of the package substrate 300 and the first wire 610, or is transmitted to the upper semiconductor chip 420 through the internal wiring 320 and the first bond finger 310 of the package substrate 300 and the second wire 620.

The lower semiconductor chip 410 and the upper semiconductor chip 420 are connected in common to one external connection terminal 800, and are connected in common to one channel through the external connection terminal 800 to share the one channel. While one of the lower semiconductor chip 410 and the upper semiconductor chip 420 operates, the other is in a standby state. In an embodiment, a wire connected to a semiconductor chip that is in a standby state acts as a long stub and increases the electrical loading of the semiconductor package. In addition, in an embodiment, a signal reflected from a semiconductor chip in a standby state is input to a semiconductor chip in operation through a wire connected to the semiconductor chip in a standby state to act as noise, thereby reducing the valid window size of data at the channel/system level of the semiconductor package and a system in which the semiconductor package is mounted, deteriorating signal integrity and thus hindering the high-speed operation of the semiconductor package/system.

Referring again to FIG. 1 and FIG. 2, according to embodiments of the present disclosure, a signal input to the external connection terminal 70A from the external device is transmitted to the first semiconductor chip 10 through the redistribution pattern 62 and the first vertical wire W1, or is transmitted to the second semiconductor chip 20 through the redistribution pattern 62, the first vertical wire W1, the first bonding pad 11, the first trace 13, the first connection pad 12 and the first connection bump 41. A stub, in an embodiment, is the first connection bump 41, and the length of the stub is the same as the height of the first connection bump 41. The length of the stub in embodiments of the present disclosure is shorter than the first wire 610 or the second wire 620 acting as a stub in FIG. 9. By using an embodiment of the present disclosure, because the length of a stub is shortened, signal integrity may be improved while minimizing electrical loading of a package, thereby enabling a high-speed operation.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

1. A semiconductor package comprising:
a first semiconductor chip including a first bonding pad and a first connection pad connected to the first bonding pad;
a second semiconductor chip stacked on the first semiconductor chip, and including a second bonding pad connected to the first connection pad by a first connection bump;
a first vertical wire disposed on the first bonding pad;
a molding layer sealing the first and second semiconductor chips and the first vertical wire; and
a redistribution layer disposed on the molding layer and the first vertical wire.

2. The semiconductor package according to claim 1, wherein the first and second bonding pads include data pads.

3. The semiconductor package according to claim 1, wherein the first semiconductor chip comprises:
a chip body; and
a redistribution pattern disposed on the chip body, and including the first bonding pad, the first connection pad and a trace that connects the first connection pad and the first bonding pad.

4. The semiconductor package according to claim 1, further comprising:
a third bonding pad included in the first semiconductor chip;
a second connection pad and a fourth bonding pad included in the first semiconductor chip and connected to each other;
a fifth bonding pad included in the second semiconductor chip, and connected to the second connection pad by a second connection bump;
a second vertical wire disposed on the third bonding pad, and sealed by the molding layer; and
a third vertical wire disposed on the fourth bonding pad, and sealed by the molding layer.

5. The semiconductor package according to claim 4, wherein the third and fifth bonding pads include command/address pads or chip select pads.

6. The semiconductor package according to claim 4, wherein
the first and third bonding pads are connected to an integrated circuit that is included within the first semiconductor chip, and
the second connection pad and the fourth bonding pad are isolated from the integrated circuit.

7. The semiconductor package according to claim 4, wherein the first semiconductor chip comprises:
a chip body;
a first redistribution pattern disposed on the chip body, and including the first bonding pad, the first connection pad and a first trace that connects the first connection pad and the first bonding pad; and
a second redistribution pattern disposed on the chip body, and including the second connection pad, the fourth bonding pad and a second trace that connects the second connection pad and the fourth bonding pad.

8. The semiconductor package according to claim 4, wherein
the first semiconductor chip includes a first pad column, a second pad column disposed between the first pad column and a side surface of the first semiconductor chip, and a third pad column disposed between the first pad column and the second pad column,
the first and third bonding pads are included in the second pad column,
the first and second connection pads are included in the first pad column, and
the fourth bonding pad is included in the third pad column.

9. The semiconductor package according to claim 8, wherein the second semiconductor chip is offset-stacked on the first semiconductor chip to vertically overlap the first pad column and expose the second and third pad columns.

10. The semiconductor package according to claim 4, further comprising
external connection terminals disposed on the redistribution layer,
wherein the first, second and third vertical wires are connected to different external connection terminals.

11. The semiconductor package according to claim 1, further comprising
an adhesive layer attaching the first semiconductor chip and the second semiconductor chip.

12. A semiconductor package comprising:
a first semiconductor chip including a first bonding pad and a first connection pad connected to the first bonding pad;
a second semiconductor chip offset-stacked on the first semiconductor chip to expose the first bonding pad, and including a second bonding pad connected to the first connection pad by a first connection bump;
a third semiconductor chip stacked on the second semiconductor chip, and including a third bonding pad and a second connection pad connected to the third bonding pad;
a fourth semiconductor chip offset-stacked on the third semiconductor chip to expose the third bonding pad, and including a fourth bonding pad connected to the second connection pad by a second connection bump;
a first vertical wire disposed on the first bonding pad;
a second vertical wire disposed on the third bonding pad;
a molding layer sealing the first, second, third and fourth semiconductor chips and the first and second vertical wires; and
a redistribution layer disposed on the molding layer and the first and second vertical wires.

13. The semiconductor package according to claim 12, wherein the first, second, third and fourth bonding pads include data pads.

14. The semiconductor package according to claim 12, further comprising
external connection terminals disposed on the redistribution layer,
wherein the first vertical wire and the second vertical wire are connected to different external connection terminals.

15. The semiconductor package according to claim 12, further comprising:
a fifth bonding pad included in the first semiconductor chip;
a third connection pad and a sixth bonding pad included in the first semiconductor chip and connected to each other;
a seventh bonding pad included in the second semiconductor chip, and connected to the third connection pad by a third connection bump;
an eighth bonding pad included in the third semiconductor chip;
a fourth connection pad and a ninth bonding pad included in the third semiconductor chip and connected to each other;
a tenth bonding pad included in the fourth semiconductor chip, and connected to the fourth connection pad by a fourth connection bump;
a third vertical wire disposed on the fifth bonding pad, and sealed by the molding layer;
a fourth vertical wire disposed on the sixth bonding pad, and sealed by the molding layer;
a fifth vertical wire disposed on the eighth bonding pad, and sealed by the molding layer; and
a sixth vertical wire disposed on the ninth bonding pad, and sealed by the molding layer.

16. The semiconductor package according to claim 15, wherein the fifth, seventh, eighth and tenth bonding pads include command/address pads or chip select pads.

17. The semiconductor package according to claim 15, wherein the first semiconductor chip comprises:
a first chip body;
a first redistribution pattern disposed on the first chip body, and including the first bonding pad, the first connection pad and a first trace that connects the first connection pad and the first bonding pad; and
a second redistribution pattern disposed on the first chip body, and including the third connection pad, the sixth bonding pad and a second trace that connects the third connection pad and the sixth bonding pad; and,
the third semiconductor chip further comprises:
a second chip body;
a third redistribution pattern disposed on the second chip body, and including the third bonding pad, the second connection pad and a third trace that connects the second connection pad and the third bonding pad; and
a fourth redistribution pattern disposed on the second chip body, and including the fourth connection pad, the ninth bonding pad and a fourth trace that connects the fourth connection pad and the ninth bonding pad.

18. The semiconductor package according to claim 15, wherein the fourth semiconductor chip is disposed between the first, third and fourth vertical wires and the second, fifth and sixth vertical wires.

19. The semiconductor package according to claim 12, wherein
the second semiconductor chip is first offset-stacked on the first semiconductor chip,
the third semiconductor chip is second offset-stacked on the second semiconductor chip in a direction the same as a direction in which the second semiconductor chip is first offset-stacked on the first semiconductor chip, and
the fourth semiconductor chip is third offset-stacked on the third semiconductor chip in a direction opposite to the direction in which the second semiconductor chip is first offset-stacked on the first semiconductor chip.

20. The semiconductor package according to claim 12, further comprising:
a first adhesive layer attaching the first semiconductor chip and the second semiconductor chip;
a second adhesive layer attaching the second semiconductor chip and the third semiconductor chip; and
a third adhesive layer attaching the third semiconductor chip and the fourth semiconductor chip.
